(19) United States
(12) Patent Application Publication
(10) Pub. No.: US 2022/0415871 A1
(43) Pub. Date: Dec. 29, 2022

(54) PIXEL AND DISPLAY DEVICE

(71) Applicant: STMicroelectronics (Grenoble 2) SAS, Grenoble (FR)

(72) Inventor: Jonathan STECKEL, Corenc (FR)

(73) Assignee: STMicroelectronics (Grenoble 2) SAS, Grenoble (FR)

(21) Appl. No.: 17/845,232

(22) Filed: Jun. 21, 2022

(30) Foreign Application Priority Data
Jun. 23, 2021 (FR) 2106696

(51) Int. Cl. H01L 25/16

(52) U.S. Cl. CPC H01L 25/167; H01L 33/32

(57) ABSTRACT

A pixel includes a sensing element and red, green and blue first light emitters. The number of light emitters of each green, red and blue color is equal in each pixel. The pixel may further include a second light emitter which emits light that is different from blue light, green light or red light.

### PRIORITY CLAIM

This application claims the priority benefit of French Application for Patent No. 2106696, filed on Jun. 23, 2021, the content of which is hereby incorporated by reference in its entirety to the maximum extent allowable by law.

### TECHNICAL FIELD

The present disclosure relates generally to a display and, more precisely, to a pixel integrating its own control circuit, wherein the pixel is a component of the display.

### BACKGROUND

Display pixels integrating a control circuit are generally made of light emitting diodes (LEDs). The LEDs are, usually, formed on a substrate in which the control circuit is manufactured in CMOS technology. According to another technology, the LEDs are formed on a substrate (typically Sapphire or Silicon) and the control circuit is formed on another substrate (typically in CMOS technology on Silicon) and the two substrates are brought together to form display pixels.

There is a need to improve these display pixels and address all or some of the drawbacks of known display pixels.

### SUMMARY

One embodiment provides a pixel comprising a sensing element and red, green and blue first light emitters, the number of light emitters of each green, red and blue color being equal.

Another embodiment provides a method including the formation, within a same pixel, of a sensing element and red, green and blue first light emitters, the number of light emitters of each green, red and blue color being equal.

According to an embodiment, the red, green and blue first light emitters and the sensing element are formed on or transferred over to a unique CMOS substrate.

According to an embodiment, the substrate fits inside a cube having dimensions of less than 100 μm, preferably less than 50 μm.

According to an embodiment, each first light emitter fits inside a cube having dimensions of less than 15 μm, preferably less than 5 μm.

According to an embodiment, the pixel or the method comprises an addressing circuit.

According to an embodiment, the pixel or the method comprises a unique blue first light emitter, a unique red first light emitter and a unique green first light emitter.

According to an embodiment, the pixel or the method comprises two blue first light emitters, two red first light emitters and two green first light emitters.

According to an embodiment, the sensing element is a Quantum Film PbS quantum dot photodetector and the first light emitters are made of GaN.

According to an embodiment, the pixel or the method comprises a second light emitter which is different from a blue light emitter, a green light emitter or a red light emitter.

According to an embodiment, the second light emitter is a time of flight compatible light emitter or a short wave infrared compatible light emitter, preferably selected in the list of an electroluminescent quantum dot, a photoluminescent quantum dot, an edge emitting laser or a vertical-cavity surface-emitting laser.

According to an embodiment, the sensing element is a PbS quantum dot photodetector, the first light emitters are made of GaN and the second light emitter is a short wave infrared compatible light emitter.

According to an embodiment, the sensing element is an InAs or InAsSb quantum dot photodetector, the first light emitters are made of GaN and the second light emitter is a short wave infrared compatible light emitter.

According to an embodiment, the sensing element is a photodetector, preferably selected in the list of Time of Flight compatible photodetector and short wave infrared compatible photodetector.

According to an embodiment, the photodetector is based on Gallium Nitride, on Silicon, on Indium gallium arsenide or on a Quantum dot.

According to an embodiment, the sensing element is an actuator, preferably selected in the list of piezo-actuator, electrostrictor actuator and capacitive micromachined ultrasonic transducer actuator.

According to an embodiment, at least one of the red, green and blue first light emitters is a epitaxially grown diode and/or at least one of the red, green and blue first light emitters is a molecule beam epitaxially grown diode and/or at least one of the red, green and blue first light emitters is a quantum dot electroluminescent device.

One other embodiment provides a display device comprising pixels as described, in which pixels are organized in an array.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 illustrates an embodiment of a display device;

FIG. 2 illustrates an embodiment of a first pixel; and

FIG. 3 illustrates another embodiment of a first pixel.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the pixel addressing circuits have not been described but are compatible with usual addressing circuits.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

In the following disclosure, an electromagnetic radiation the wavelengths of which are between 400 nm and 700 nm is called the visible light. In particular, in the visible light, a red light has all its wavelengths comprised between 600 nm and 700 nm, a blue light has all its wavelengths comprised between 450 nm and 490 nm, a green light has all its wavelengths comprised between 490 nm and 550 nm. In the following disclosure, an electromagnetic radiation the wavelengths of which are between 700 nm and 1 mm is called the infrared light (IR). In the infrared light, in particular an electromagnetic radiation the wavelengths of which are between 700 nm and 1 μm is called the near infrared light (near infrared radiation—NIR) and radiation the wavelengths of which are between 1 μm and 3 μm is called the short wave infrared light (short wave infrared radiation—SWIR).

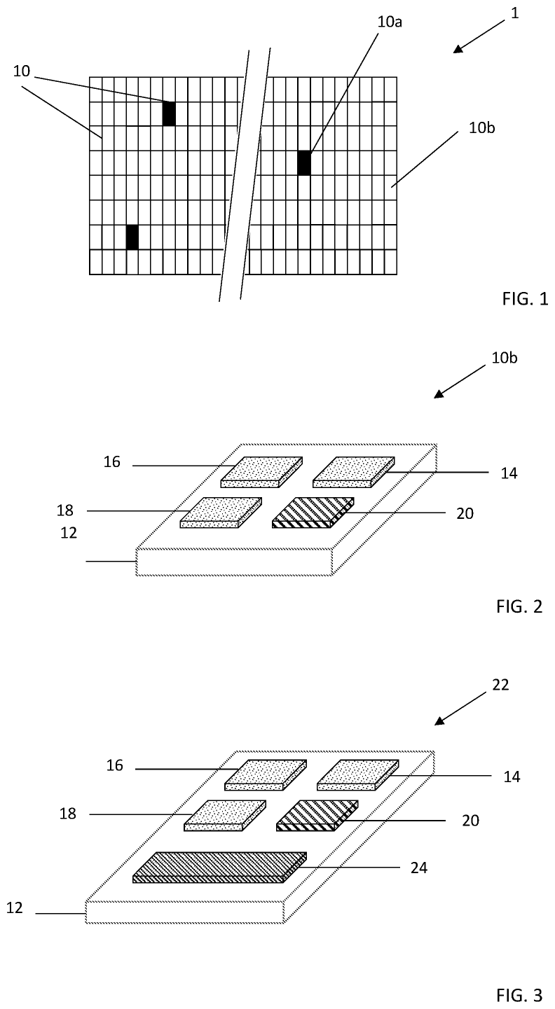

FIG. 1 illustrates an embodiment of a display device 1. The display device 1 comprises several pixels 10 organized in matrix, in lines and columns, each pixel being a first pixel 10a or a second pixel 10b. According to an embodiment, the display device comprises at least one first pixel 10a and at least one second pixel 10b. According to an embodiment, at least 0.1% of pixels 10 are first pixels 10a. According to an embodiment, at least, 1% of pixels 10 are first pixels 10a. According to an embodiment, at least, 10% of pixels 10 are first pixels 10a.

FIG. 2 illustrates an embodiment of a first pixel 10a. The pixel 10a integrates a control circuit in CMOS technology. Such a pixel is a multidimensional pixel or intelligent pixel. Some pixels of this kind are commercially known as “smart pixel”.

The pixel 10a illustrated in FIG. 2 comprises, on a Complementary Metal Oxide Semiconductor (CMOS) substrate 12, a green light emitter 14, a red light emitter 16, a blue light emitter 18 and a sensing element 20.

According to an embodiment, there is one and only one sensing element 20 per pixel 10a.

According to an embodiment, the substrate 12 is made of a semiconductor material, for example of Silicon (Si). For example, the substrate 12 is carried by a rigid or flexible support (not explicitly illustrated). The support is, for example, made of glass or plastic. The support receives, for example, several pixels 10 organized in an array.

For example, the light emitters 14, 16 and 18 and the sensing element 20 are realized together on and, for example in, a first CMOS substrate and then transferred on the CMOS substrate 12. For example, the assembly of the three light emitters 14, 16 and 18 and the sensing element 20 is transferred from the first CMOS substrate to the substrate 12 by a pick and place process.

Each pixel 10a comprises, for example, an addressing circuit configured to address the light emitters 14, 16 and 18 and the sensing element 20. The addressing circuit is, for example, formed in and on the substrate 12. According to an embodiment, an addressing circuit is configured to address the light emitters and the sensing element of one pixel 10a and, for example, the light emitters and the sensing element of one or more pixels 10b, close to the pixels 10a.

According to the embodiment illustrated in FIG. 2, the light emitters 14, 16 and 18 and the sensing element 20 are organized as a Bayer matrix, which usually comprises two blue, one green and one red light emitters, but in this case one of the two blue light emitters is replaced with the sensing element 20. According to the embodiment illustrated in FIG. 2, the light emitters 14, 16 and 18 and the sensing element 20 are organized in a matrix comprising two lines and two columns. In FIG. 2, the red light emitter 16 and the sensing element 20 are located, in the matrix, diagonally opposite each other and the first line comprises the red light emitter 16 and the green light emitter 14 and the second line comprises the blue light emitter and the sensing element 20. However, in practice, the light emitters 14, 16 and 18 and the sensing element 20 can be organized, in the matrix, differently.

According to an embodiment, each substrate 12 has the shape of a cube or a parallelepiped. For example, the pixels 10a fit inside a cube having dimensions of less than 100 μm, preferably less than 50 μm. Dimensions of a cube means the length of the edges of the cube.

According to an embodiment, each light emitter 14, 16 and 18 has the shape of a cube or a parallelepiped, typically with rectangular surface. For example, each light emitter 14, 16 and 18 fits inside a cube having dimensions of less than 15 μm, preferably less than 5 μm.

According to an embodiment, at least one of the light emitters 14, 16 and 18 is a Gallium Nitride (GaN) epitaxially grown diode and/or at least one of the light emitters 14, 16 and 18 is a GaN molecule beam epitaxially (MBE) grown diode.

According to an embodiment, the light emitters 14, 16 and 18 are all made in the same technology (epitaxially grown diode, or MBE grown diode) are made in a different technology.

For example, the grown diodes are made in a technology planar or in nano-wires.

According to an embodiment, the pixel 10a comprises, instead of one light emitter 14, 16 and 18 of each color, several light emitters of each color. According to an embodiment, the number of red light emitters 16 is equal to the number of green light emitters 14 and is equal to the number of blue light emitters 18. For example, the pixel 10a comprises two blue light emitters 18, two red light emitters 16 and two green light emitters 14.

For example, the sensing element 20 is made of Indium Arsenide Antimony (InAsSb), of Indium Arsenide (InAs), of Lead Sulfur (PbS), etc. The QD photodetector has a high performance detectivity in the visible, near infrared, short wave infrared and extended short wave infrared wave length ranges. For example, the sensing element 20 is formed on and/or in the substrate 12 or formed on a separate substrate and transferred over onto substrate 12. For example, the QD photodetector is a microcamera or a micro image sensor.

According to a first example, in the pixel 10a, red, green and blue light emitters are made of GaN and the sensing element 20 is a Lead Sulfur QD photodetector. This example can be used as a visible and near or short wave infrared camera.

A display device comprising several pixels 10a as described uses computation circuits in order to create the resulting image.

The sensing element 20 can be an ambient light sensor. In this case, the display device 1 has the property of adapting the emitter's luminosity according to the ambient light.

The sensing element 20 can be a gesture sensor. In this case, the display device 1 has the property of adapting the emitter's luminosity according to the proximity of the user.

The sensing element 20 can be an ambient light sensor. In this case, the display device 1 has the property of adapting the emitter's luminosity according to the gesture of the user.

The sensing element 20 can be a biometric sensor, like face ID sensor.

The sensing element 20 can be a touch sensor.

FIG. 3 illustrates another example of a pixel 22.

The pixel 22 illustrated in FIG. 3 is similar to the pixel 10a illustrated in FIG. 2 with the difference that the sensing element 20 is coupled with a light emitter 24 which emits light that is neither blue, nor green, nor red. The light emitter 24 is different from the red 16, the blue 18 and the green 14 light emitters. According to an embodiment, the light emitter 24 emits in at least one among the NIR, the SWIR and the extended SWIR plus optionally visible wavelengths. In other words, light emitter 24 does not emit visible light only.

According to an embodiment, the light emitter 24 is located apart from and next to the matrix comprising the light emitters 14, 16 and 18 and the sensing element 20. According to an embodiment, there is one and only one light emitter 24 per pixel 22.

The light emitter 24 is, for example, a laser diode permitting to the sensing element 20 to detect a time of flight. According to an embodiment, the light emitter 24 is a Vertical-Cavity Surface-Emitting Laser (VCSEL), an edge emitting laser (EEL) or an electroluminescent Quantum Dot device called a QD-LED. According to an embodiment, the light emitter 24 is a photoluminescent Quantum Dot (QD PL) based on the combination of a QD NIR or SWIR light emitting film or structure and a visible light excitation pump made of GaN. For example, the light emitter 24 is formed on and/or in the substrate 12 or formed on a separate substrate and transferred over onto substrate 12.

In the pixel 22 illustrated in FIG. 3, the light emitters 14, 16 and 18 are similar to the light emitters 14, 16 and 18 of the pixel 10a illustrated in FIG. 2.

According to a second example, in the pixel 22, red, green and blue light emitters are made of GaN, the sensing element is a Lead Sulfur QD photodetector and the light emitter 24 is a SWIR illuminator. The SWIR illuminator is preferably a QD-LED, a QD PD, a VCSEL or an EEL. This example of pixel is used as health and/or wellness monitoring element as a heart rate monitoring sensor, a blood oxygen monitoring sensor, etc. Indeed, SWIR light provides a very deep penetration through the skin with less illumination intensity needed while shorter wavelengths provide a pattern of blood vessels under the skin in the finger that are unique and different for each person. This example creates a new form of individual identification technology built into the display.

According to a third example, in the pixel 22, red, green and blue light emitters are made of GaN, the sensing element is an InAS QD photodetector and the light emitter 24 is a SWIR illuminator. The SWIR illuminator is preferably a QD-LED, a QD PD, a VCSEL or an EEL. This example of pixel is used as a touch, gesture or object recognition and proximity sensing enabled by ToF sensing.

An advantage of the described embodiments is that some pixels integrate emitter elements and detector elements.

An advantage of the described embodiments is that some pixels integrate sensing technology into micro-Led based display technology instead of putting sensing technology behind the display.

An advantage of the described embodiments is that the smart display is more powerful, less costly and thinner than a sensing element positioned behind the display.

Various embodiments and variants have been described. Those skilled in the art will understand that certain features of these embodiments can be combined and other variants will readily occur to those skilled in the art. In particular, the variants proposed to the pixel illustrated in FIG. 2 can be combined with the embodiments illustrated in FIG. 3.

Finally, the practical implementation of the embodiments and variants described herein is within the capabilities of those skilled in the art based on the functional description provided hereinabove.

1. A display device, comprising:
a plurality of first pixels organized in an array and formed together on a first unique CMOS substrate and transferred to a surface of a second unique CMOS substrate;
wherein at least one first pixel comprises a quantum dot photodetector;
wherein each first pixel comprises red, green and blue first light emitters made of GaN; and
wherein a number of light emitters of each green, red and blue color in each first pixel is equal.

2. The display device according to claim 1, wherein the first pixel fits inside a cube having dimensions of less than 100 μm.

3. The display device according to claim 1, wherein the first pixel fits inside a cube having dimensions less than 50 μm.

4. The display device according to claim 1, wherein each first light emitter fits inside a cube having dimensions of less than 15 μm.

5. The display device according to claim 1, wherein each first light emitter fits inside a cube having dimensions of less than 5 μm.

6. The display device according to claim 1, wherein each first pixel comprises an addressing circuit.

7. The display device according to claim 1, wherein said red, green and blue first light emitters comprise a unique blue first light emitter, a unique red first light emitter and a unique green first light emitter.

8. The display device according to claim 1, wherein said red, green and blue first light emitters comprise two blue first light emitters, two red first light emitters and two green first light emitters.

9. The display device according to claim 1, wherein at least 0.1% of the first pixels comprises a quantum dot photodetector.

10. The display device according to claim 1, wherein at least 1% of the first pixels comprises a quantum dot photodetector.

11. The display device according to claim 1, wherein at least 10% of the first pixels comprises a quantum dot photodetector.

12. The display device according to claim 1, wherein each first pixel further comprises a second light emitter which emits light that is different from blue light, green light or red light.

13. The display device according to claim 12, wherein the second light emitter is a time of flight compatible light emitter.

14. The display device according to claim 12, wherein the second light emitter is a short wave infrared compatible light emitter.

15. The display device according to claim 12, wherein the second light emitter is selected from the group consisting of: an electroluminescent quantum dot, a photoluminescent quantum dot, an edge emitting laser and a vertical-cavity surface-emitting laser.

16. The display device according to claim 1, wherein the quantum dot photodetector enables ambient light sensing.

17. The display device according to claim 1, wherein the quantum dot photodetector enables proximity sensing.

18. The display device according to claim 1, wherein the quantum dot photodetector enables gesture sensing.

19. The display device according to claim 1, wherein the quantum dot photodetector enables biometric sensing.

20. A display device, comprising:
a plurality of pixels organized in an array and formed together on a first unique CMOS substrate and transferred to a surface of a second unique CMOS substrate;
wherein at least one first pixel comprises a silicon photodetector; and
wherein each pixel comprises red, green and blue first light emitters made of GaN;
wherein a number of light emitters of each green, red and blue color in each pixel is equal.
